(19) United States
(12) Patent Application Publication
(10) Pub. No.: US 2026/0196972 A1
(43) Pub. Date: Jul. 9, 2026

(54) Power Supply Circuit And Circuit Device

(71) Applicant: SEIKO EPSON CORPORATION, Tokyo (JP)

(72) Inventor: Shinichi SEKITA, Suwa (JP)

(21) Appl. No.: 19/443,536

(22) Filed: Jan. 8, 2026

(30) Foreign Application Priority Data
Jan. 9, 2025 (JP) 2025-003302

(51) Int. Cl. H03F 1/30; H02J 7/00; H03F 3/45

(52) U.S. Cl. CPC H03F 1/301; H02J 7/855; H03F 3/45183; H03F 3/45273; H03F 2200/555; H03F 2203/5021

(57) ABSTRACT

A power supply circuit includes an amplifier including a differential pair configured with a first transistor and a second transistor, and a load section as a load of the differential pair. Further, in the power supply circuit, an input voltage is input to the gate of the first transistor, and the drain and the gate of the second transistor are coupled to each other. Further, the amplifier outputs, as an output voltage from the drain of the second transistor, a voltage obtained by offsetting a work function difference voltage between the first transistor and the second transistor by an offset voltage based on a size ratio between the first transistor and the second transistor.

The present application is based on, and claims priority from JP Application Serial Number 2025-003302, filed January 9, 2025, the disclosure of which is hereby incorporated by reference herein in its entirety.

### BACKGROUND

### Technical Field

The present disclosure relates to a power supply circuit, a circuit device, and the like.

### Related Art

In the past, various proposals have been made for a voltage generation circuit in which the temperature dependence of the output voltage is reduced. JP-A-2005-340337 discloses a voltage generation circuit that includes a differential amplifier circuit and a voltage divider circuit coupled with a voltage follower coupling to thereby improve the temperature characteristic of the output voltage.

JP-A-2005-340337 is an example of the related art.

The voltage generation circuit disclosed in JP-A-2005-340337 includes a resistor, and therefore has a problem that the chip area increases. It is desirable to propose a method of constructing a power supply circuit that achieves both an improvement in temperature characteristics of the output voltage and a reduction in cost.

### SUMMARY

An aspect of the present disclosure relates to a power supply circuit including a first amplifier including a first differential pair configured with a first transistor and a second transistor, and a first load section as a load of the first differential pair, wherein an input voltage is input to a gate of the first transistor, a drain and a gate of the second transistor are coupled to each other, and the first amplifier outputs, as a first output voltage from the drain of the second transistor, a voltage obtained by offsetting a first work function difference voltage between the first transistor and the second transistor by a first offset voltage based on a size ratio between the first transistor and the second transistor.

Further, another aspect of the present disclosure relates to a circuit device including the power supply circuit described above, a discharge circuit configured to supply power to an outside based on a battery voltage from a battery, and a discharge control circuit configured to control the discharge circuit, wherein the power supply circuit operates based on the battery voltage to output a power supply voltage based on the first output voltage, and the discharge control circuit operates based on the power supply voltage.

### BRIEF DESCRIPTION OF THE DRAWINGS

FIG. 1 is a diagram illustrating a configuration example of a circuit device including a power supply circuit according to the present embodiment.

FIG. 2 is a diagram illustrating a configuration example of the power supply circuit according to the present embodiment.

FIG. 3 is a diagram showing a reference example.

FIG. 4 is a diagram illustrating functions and advantages of the present embodiment.

FIG. 5 is a diagram illustrating a more detailed configuration example of the power supply circuit of the present embodiment.

FIG. 6 is another diagram illustrating a more detailed configuration example of the power supply circuit of the present embodiment.

FIG. 7 is a diagram illustrating another configuration example of the power supply circuit of the present embodiment.

### DESCRIPTION OF EMBODIMENTS

A preferred embodiment of the present disclosure will hereinafter be described in detail. Note that the present embodiment described below does not unduly limit the content set forth in the appended claims, and some of the components described in the present embodiment may not be essential elements.

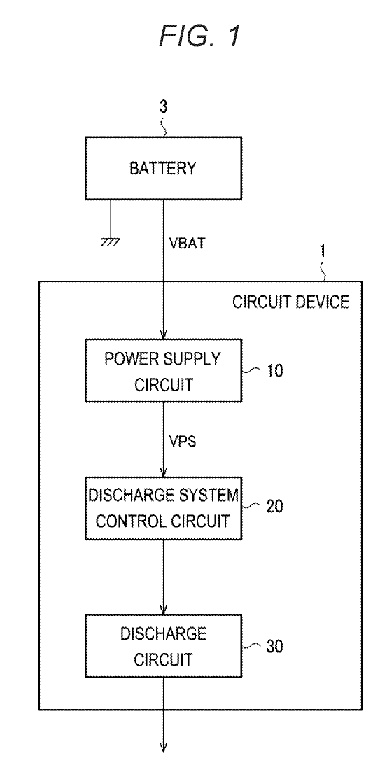

FIG. 1 is a diagram illustrating a configuration example of a circuit device 1 including a power supply circuit 10 of the present embodiment. The circuit device 1 includes the power supply circuit 10, a discharge control circuit 20, and a discharge circuit 30. Although described later in detail, the power supply circuit 10 outputs a power supply voltage VPS based on a battery voltage VBAT from a battery 3. The battery 3 is, for example, a rechargeable secondary battery such as a lithium battery or a nickel battery.

The discharge control circuit 20 performs various types of control to be performed while discharging the battery 3. Specifically, for example, the discharge control circuit 20 operates based on the power supply voltage VPS to control the discharge circuit 30. The discharge control circuit 20 can be realized by a logic circuit generated by an automatic placement and routing method such as a gate array, or various types of processors such as a microcomputer.

The discharge circuit 30 supplies a voltage to an outside of the circuit device 1. That is, the discharge circuit 30 is a power supply circuit that supplies a voltage to the outside based on the discharge of the battery 3. For example, the discharge circuit 30 supplies a voltage to a device such as a DSP or a microcomputer. As described above, the circuit device 1 of the present embodiment operates as a discharge system circuit that supplies a voltage to an external device due to the discharge of the battery 3.

Note that the configuration of the circuit device 1 of the present embodiment is not limited to FIG. 1, and various modified implementations such as addition of other components can be made. For example, the circuit device 1 may further include a charge system circuit. Although detailed descriptions and illustration are omitted, the charge system circuit includes, for example, a power receiving circuit, a charge system control circuit, and a charge circuit. For example, the charge system control circuit controls the power receiving circuit and the charge circuit, the power receiving circuit receives electrical power from an external power transmission device (not illustrated), and the charge circuit charges the battery 3 based on the rectified voltage output by the power receiving circuit. In this way, it is possible to make the circuit device 1 operate as a power reception device. Thus, a contactless power transmission system can be constructed by combining the circuit device 1 and that power transmission device. The contactless power transmission system can be used for charging an electronic apparatus, for example. The electronic apparatus is, for example, a hearing aid, a wristwatch, a biometric information measurement apparatus, a mobile information terminal, a cordless telephone, a shaver, an electric toothbrush, a wrist computer, a handy terminal, in-vehicle equipment, a hybrid vehicle, an electric vehicle, an electric motorcycle, or an electric bicycle. For example, when the hearing aid is used as the electronic apparatus, the power reception device including the circuit device 1 of the present embodiment and the load including the battery 3 correspond to earphones, and the power transmission device corresponds to a charging case.

These electronic apparatuses are required to stably operate in a wider temperature range. In addition, there is a demand for a reduction in price of these electronic apparatuses, and a reduction in the chip area related to the circuit device 1 can be cited as one of the measures for reducing the cost. The method of the present embodiment relates to the power supply circuit 10 that achieves both the improvement in the temperature characteristics of the output voltage and the reduction in cost, and the circuit device 1 including the power supply circuit 10.

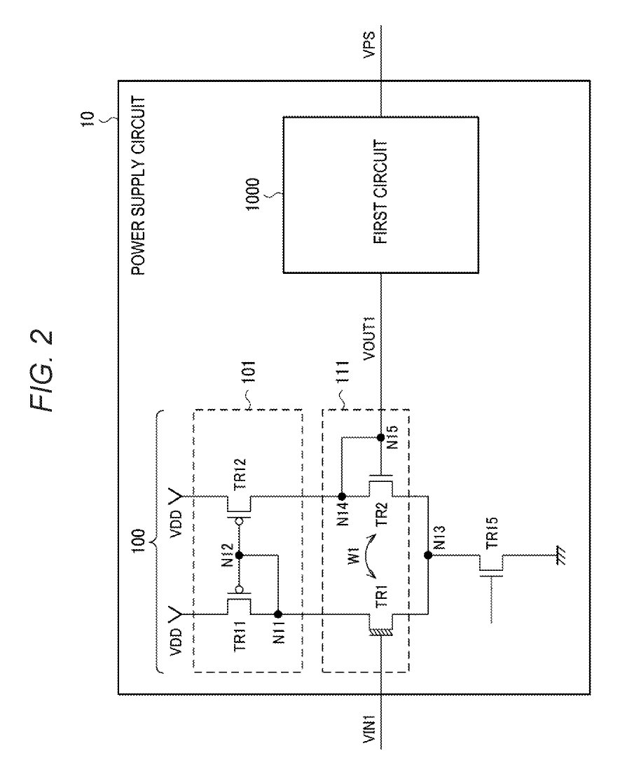

FIG. 2 is a diagram illustrating a configuration example of the power supply circuit 10. The power supply circuit 10 includes a first amplifier 100. The first amplifier 100 includes a first load section 101 and a first differential pair 111. Note that in the following description, unless otherwise specified, a transistor that appears in the present embodiment is an enhancement type MOS transistor. More specifically, transistors appearing in other portions than the description of the first differential pair 111 and a second differential pair 222 described later are all enhancement type MOS transistors.

Further, the following description does not preclude an application of the power supply circuit 10 of the present embodiment to other circuit devices than the circuit device 1 in FIG. 1. For example, hereinafter, the external power supply voltage to be supplied to the power supply circuit 10 is described as a "voltage VDD" for the sake of convenience, but when the power supply circuit 10 is applied to the circuit device 1 in FIG. 1, it may be considered that the battery voltage VBAT supplied from the battery 3 corresponds to the voltage VDD.

The first load section 101 is a load of the first differential pair 111. For example, the first load section 101 includes a transistor TR11 as a P-type transistor and a transistor TR12 as a P-type transistor, and forms a current mirror circuit with the transistor TR11 and the transistor TR12. More specifically, the transistor TR11 has the source coupled to a node at the voltage VDD side, the drain coupled to a node N11, and the gate coupled to a node N12. Note that the node at the voltage VDD side is hereinafter referred to as a "power supply node". The node N11 and the node N12 are coupled to each other. Further, the transistor TR12 has the source coupled to a power supply node, the drain coupled to a node N14, and the gate coupled to the node N12.

The first differential pair 111 is configured with a first transistor TR1 and a second transistor TR2. The first transistor TR1 has the drain coupled to the node N11, and the source coupled to a node N13. Further, an input voltage VIN1 is input to the gate of the first transistor TR1. The second transistor TR2 has the drain coupled to the node N14, the source coupled to the node N13, and the gate coupled to a node N15.

Note that it is assumed that the input voltage VIN1 is a ground voltage and the ground voltage is 0 V in the following description for the sake of convenience of easiness in understanding the method of the present embodiment, but this is illustrative only, and it is sufficient for the input voltage VIN1 to be a constant voltage and a specific level thereof may be appropriately determined.

In addition, a transistor TR15 in FIG. 2 is an N-type transistor, and has the drain coupled to the node N13, the source coupled to a node at the ground side, and the gate coupled to a bias voltage generation circuit (not illustrated). Note hereinafter that, the node at the ground side is referred to as a ground node, and the bias voltage generation circuit (not illustrated) is simply referred to as a bias voltage generation circuit. Accordingly, the transistor TR15 operates as a current source of the first amplifier 100 based on a bias voltage output from the bias voltage generation circuit.

The first amplifier 100 configured in such a manner outputs a first output voltage VOUT1. Specifically, the first output voltage VOUT1 is output from the node N14 in FIG. 2. In addition, the drain and the gate of the second transistor TR2 are coupled by being coupled to the node N14 and the node N15. That is, a node coupled to the gate of the first transistor TR1 corresponds to a node at an inverting terminal side of the first amplifier 100, the node N15 corresponds to a node at a non-inverting terminal side of the first amplifier 100, and the node N14 corresponds to an output node of the first amplifier 100.

Further, in the present embodiment, the work function of the gate electrode of the first transistor TR1 and the work function of the gate electrode of the second transistor TR2 are different. The work function means the height of a potential barrier that must be run over on that surface in order for an electron to escape from a substance, and corresponds to an absolute value of energy of the Fermi level of the substance when the vacuum potential is assumed to be 0. For example, by using N-type polysilicon as the material of the gate electrode of one transistor and using P-type polysilicon as the material of the gate electrode of the other transistor, the gate electrodes can be made different in work function from each other. In this way, a difference between a threshold voltage of the first transistor TR1 and a threshold voltage of the second transistor TR2 becomes a difference between the work function of the gate electrode of the first transistor TR1 and the work function of the gate electrode of the second transistor TR2, and that difference is referred to as a "first work function difference voltage W1" in the present embodiment.

An example in which N-type polysilicon is used as the material of the gate electrode of the first transistor TR1 and P-type polysilicon is used as the material of the gate electrode of the second transistor TR2 will hereinafter be described. Thus, the first work function difference voltage W1 having a positive level can be obtained. That is, in the present embodiment, the first transistor TR1 is an N-type transistor of the depletion type, and the second transistor TR2 is an N-type transistor of the enhancement type. In this way, the first output voltage VOUT1, which is a voltage corresponding to the magnitude of the first work function difference voltage W1, is output from the first amplifier 100. Note that the above is illustrative only, and the first transistor TR1 is not required to be the depletion type transistor as long as the material of the gate electrode of one of the first transistor TR1 and the second transistor TR2 can be made different from the material of the gate electrode of the other.

More specifically, for example, it is assumed that the threshold voltage of the first transistor TR1 is set to "-0.52 V", and the threshold voltage of the second transistor TR2 is set to "0.45 V". In this case, the output voltage output from the output node of the first amplifier 100 is "0.97 V" unless a first offset voltage described later is considered. Note that "0.97 V" is hereinafter used for the sake of convenience, but is illustrative only.

Further, in the present embodiment, the first transistor TR1 and the second transistor TR2 are different in size from each other. It is sufficient to appropriately determine how much the size is made different taking a difference between the desired first output voltage VOUT1 and the first work function difference voltage W1 into consideration. For example, it is assumed that the first work function difference voltage W1 is "0.97 V" as described above although the first output voltage VOUT1 is wanted to be set to "0.9 V”. That is, it is necessary to generate an offset voltage of "-0.07 V”. In this case, it is sufficient to set the size of the second transistor TR2 such that the difference between the threshold voltage of the first transistor TR1 and the threshold voltage of the second transistor TR2 when the gate electrode materials are the same becomes "-0.07 V”. Further, in the present embodiment, the voltage of "-0.07 V”, which is the difference, is referred to as a first offset voltage.

For example, although not illustrated in detail, it is sufficient to set the gate width of the second transistor TR2 to be a predetermined multiple of the gate width of the first transistor TR1. More specifically, for example, when the predetermined multiple is six times, it is equivalent to six second transistors TR2 that are each the same in size as the first transistor TR1, and are coupled in parallel to each other. Alternatively, the gate length of the second transistor TR2 may be shortened by a certain ratio with respect to the gate length of the first transistor TR1. This is because the magnitude of the current flowing through the MOS transistor is proportional to the gate width and inversely proportional to the gate length, although the mathematical expression is omitted. By increasing the gate width of the second transistor TR2 or shortening the gate length of the second transistor TR2 in this manner, the threshold voltage of the second transistor TR2 decreases as much as the current flowing through the second transistor TR2 can be increased, and the magnitude of the voltage thus decreased becomes the first offset voltage.

Then, the first output voltage VOUT1 set to 0.9 V is input to a first circuit 1000, and the power supply voltage VPS is output from the first circuit 1000. For example, the first circuit 1000 further regulates the first output voltage VOUT1 to output the power supply voltage VPS different in voltage value from the first output voltage VOUT1. Alternatively, the first circuit 1000 may buffer the first output voltage VOUT1 to output the power supply voltage VPS the same in voltage value as the first output voltage VOUT1. A detailed example of the first circuit 1000 will be described later. Note that the first offset voltage may be a positive voltage. In that case, it is sufficient for the gate width of the second transistor TR2 to be smaller than the gate width of the first transistor TR1, or it is sufficient for the gate length of the second transistor TR2 to be shorter than the gate length of the first transistor TR1.

As described above, the power supply circuit 10 of the present embodiment includes the first amplifier 100 including the first differential pair 111 configured with the first transistor TR1 and the second transistor TR2, and the first load section 101 that is a load of the first differential pair 111. Further, in the power supply circuit 10, the input voltage VIN1 is input to the gate of the first transistor TR1, and the drain and the gate of the second transistor TR2 are coupled. Further, the first amplifier 100 outputs, as the first output voltage VOUT1, a voltage obtained by offsetting the first work function difference voltage W1 between the first transistor TR1 and the second transistor TR2 by the first offset voltage based on a size ratio between the first transistor TR1 and the second transistor TR2 from the drain of the second transistor TR2.

As described above, the power supply circuit 10 of the present embodiment includes the first amplifier 100 including the first load section 101 and the first differential pair 111, and therefore, can output a desired voltage. In addition, since the input voltage VIN1 is input to the gate of the first transistor TR1, the drain and the gate of the second transistor TR2 are coupled to each other, and the first output voltage VOUT1 is output from the drain of the second transistor TR2, the power supply circuit 10 can operate as a non-inverting amplifier circuit. Specifically, a relationship can be established in which a signal of the input voltage VIN1 is input to the non-inverting terminal of the first amplifier 100, a signal of the first output voltage VOUT1 is output from the output terminal of the first amplifier 100, and the signal of the first output voltage VOUT1 is input to the inverting terminal of the first amplifier 100 as a feedback signal. Further, since the first output voltage VOUT1 is output from the first amplifier 100 using the first work function difference voltage W1, it is not necessary to use a feedback resistor. This can reduce the chip area related to the power supply circuit 10. Accordingly, a manufacturing cost can be reduced. Further, since the magnitude of the first work function difference voltage W1 depends on the material of the gate electrode, the temperature characteristics of the first output voltage VOUT1 can be improved. Accordingly, it is possible to construct the power supply circuit 10 that achieves both the reduction of the chip area and the improvement of the temperature characteristics of the output voltage. In addition, since the first output voltage VOUT1 in which the first offset voltage based on the fact that the first transistor TR1 and the second transistor TR2 are different in the size ratio is further considered is output, it is possible to output the first output voltage VOUT1 different in magnitude from the first work function difference voltage W1. In other words, while the first work function difference voltage W1 is a voltage with a constant value determined by a process, the voltage value of the power supply voltage VPS can be set more freely by further adding the first offset voltage.

Further, the method of the present embodiment may be realized as the circuit device 1. That is, the circuit device 1 of the present embodiment includes the power supply circuit 10 described above, the discharge circuit 30 that supplies power to the outside based on the battery voltage VBAT from the battery 3, and the discharge control circuit 20 that controls the discharge circuit 30. The power supply circuit 10 operates based on the battery voltage VBAT and outputs the power supply voltage VPS based on the first output voltage VOUT1, and the discharge control circuit 20 operates based on the power supply voltage VPS. This makes it possible to obtain substantially the same advantages as those described above.

Further, in the power supply circuit 10 of the present embodiment, it is possible to arrange that the first transistor TR1 is a depletion-type MOS transistor, and the second transistor TR2 is an enhancement-type MOS transistor. In this way, since the gate electrode material of the first transistor TR1 and the gate electrode material of the second transistor TR2 are different from each other, the first amplifier 100 can be made to operate as a work function difference amplifier.

Further, in the power supply circuit 10 of the present embodiment, the size ratio between the first transistor TR1 and the second transistor TR2 may be a ratio between the gate widths or a ratio between the gate lengths. In this way, it is possible to make the threshold voltage of the first transistor TR1 and the threshold voltage of the second transistor TR2 different from each other to generate the first offset voltage.

Further, in the power supply circuit 10 of the present embodiment, the first output voltage VOUT1 may be lower than the first work function difference voltage W1 by the first offset voltage. In this way, the first amplifier 100 that outputs the first output voltage VOUT1 lower than the first work function difference voltage W1 can be constructed.

As described above, in the power supply circuit 10 of the present embodiment, the gate width of the second transistor TR2 is larger than the gate width of the first transistor TR1, or the gate length of the second transistor TR2 is shorter than the gate length of the first transistor TR1. In this way, since the current flowing through the second transistor TR2 can be increased to lower the threshold voltage, it is possible to generate the first offset voltage that applies an offset smaller than the first work function difference voltage W1.

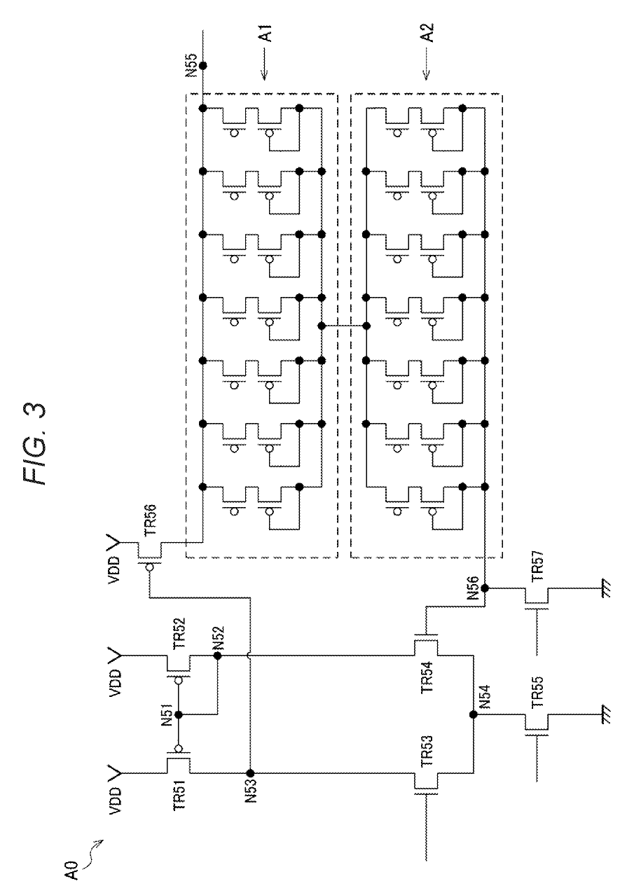

Note that as a reference example, a regulator that outputs a desired voltage without using a resistor is indicated by A0 in FIG. 3, but as described below, it can be said that the power supply circuit 10 of the present embodiment is more excellent in temperature characteristics of the power supply voltage.

The regulator indicated by A0 in FIG. 3 includes transistors TR51, TR52, TR53, TR54, TR55, TR56, and TR57. Note that the circuit indicated by a dotted-line frame of A1 is obtained by coupling a plurality of circuits in parallel to each other, wherein the circuits are each obtained by coupling a P-type transistor and a diode-connected P-type transistor in series to each other. In the circuit indicated by the dotted-line frame of A1, the circuit obtained by coupling the P-type transistor and the diode-connected P-type transistor in series to each other is hereinafter referred to as a "first P-type transistor circuit" for the sake of convenience. In addition, the sizes of the diode-connected P-type transistors in the first P-type transistor circuits are different from each other. Further, although not illustrated, the gate of each of the P-type transistors is coupled to a first decoder.

A circuit indicated by a dotted-line frame of A2 is obtained by coupling a plurality of circuits in parallel to each other, wherein the circuits are each obtained by coupling a P-type transistor and a diode-connected P-type transistor in series to each other, similarly to the circuit indicated by the dotted-line frame of A1. In the circuit indicated by the dotted-line frame of A2, the circuit obtained by coupling the P-type transistor and the diode-connected P-type transistor in series to each other is hereinafter referred to as a "second P-type transistor circuit" for the sake of convenience. In addition, the sizes of the diode-connected P-type transistors in the second P-type transistor circuits are different from each other. Further, although not illustrated, the gate of each of the P-type transistors is coupled to a second decoder. Note that in FIG. 3, the number of first P-type transistor circuits coupled in parallel to each other is seven, but this is illustrative only. The same applies to the number of second P-type transistor circuits.

The transistor TR51 as a P-type transistor and the transistor TR52 as a P-type transistor constitute a current mirror circuit. The transistor TR51 has the source coupled to the power supply node, the drain coupled to a node N53, and the gate coupled to a node N51. The transistor TR52 has the source coupled to the power supply node, the drain coupled to a node N52, and the gate coupled to the node N51. The transistor TR53 and the transistor TR54 are both N-type transistors and constitute a differential pair. The transistor TR53 has the drain coupled to the node N53, the source coupled to a node N54, and the gate coupled to the bias voltage generation circuit. The transistor TR54 has the drain coupled to the node N52, the source coupled to the node N54, and the gate coupled to a node N56. The current mirror circuit configured with the transistor TR51 and the transistor TR52 is an active load of the differential pair configured with the transistor TR53 and the transistor TR54. The transistor TR55 is an N-type transistor, and has the drain coupled to the node N54, the source coupled to the ground node, and the gate coupled to the bias voltage generation circuit. The transistor TR55 is a constant current source of the differential pair configured with the transistor TR53 and the transistor TR54.

The transistor TR56 as a P-type transistor and the transistor TR57 as an N-type transistor constitute an output stage. The transistor TR57 has the drain coupled to the node N56, the source coupled to the ground node, and the gate coupled to the bias voltage generation circuit. The transistor TR57 operates as a current source similarly to the transistor TR55. The transistor TR56 has the source coupled to the power supply node and the gate coupled to the node N53.

In addition, any of the P-type transistors in the dotted-line frame indicated by A1 is turned on by the first decoder (not illustrated). Note that for the sake of convenience, the P-type transistor that is turned on is referred to as a "primary first P-type transistor”, and the diode-connected P-type transistor to be coupled to the primary first P-type transistor is referred to as a "primary second P-type transistor”. More precisely, the drain of the primary first P-type transistor is coupled to the source of the primary second P-type transistor. In addition, any of the P-type transistors in the dotted-line frame indicated by A2 is turned on by the second decoder (not illustrated). Note that for the sake of convenience, the P-type transistor that is turned on is referred to as a "secondary first P-type transistor”, and the diode-connected P-type transistor to be coupled to the drain of the secondary first P-type transistor is referred to as a "secondary second P-type transistor”. More precisely, the drain of the secondary first P-type transistor is coupled to the source of the secondary second P-type transistor. In addition, the source of the primary first P-type transistor is coupled to the drain of the transistor TR56, the drain of the primary second P-type transistor is coupled to the source of the secondary first P-type transistor, and the drain of the secondary second P-type transistor is coupled to the node N56.

In the regulator configured as described above, an output voltage output from a node N55 is the sum of a bias voltage, which is a voltage input to the gate of the transistor TR53, the threshold voltage of the primary second P-type transistor, and the threshold voltage of the secondary second P-type transistor. Since transistors generally have manufacturing variations, variations also occur in the output voltage of the regulator at a predetermined temperature. Therefore, it is sufficient to select the first transistor circuit from the dotted-line frame indicated by A1, and select the second transistor circuit from the dotted-line frame indicated by A2 appropriately so that the output voltage at a predetermined temperature can be adjusted to a desired value. That is, the output voltage can be changed to a corresponding number of combinations to the product of the number of first P-type transistor circuits and the number of second P-type transistor circuits. In the case of FIG. 3, there are 7×7=49 combinations.

However, in the method shown in the reference example in FIG. 3, the output voltage at the predetermined temperature can be adjusted in consideration of the manufacturing variation of the transistor, but the variation in the output voltage due to a temperature change, that is, the temperature characteristic of the output voltage, cannot be taken in consideration. This is because the output voltage is adjusted by the transistor in the reference example.

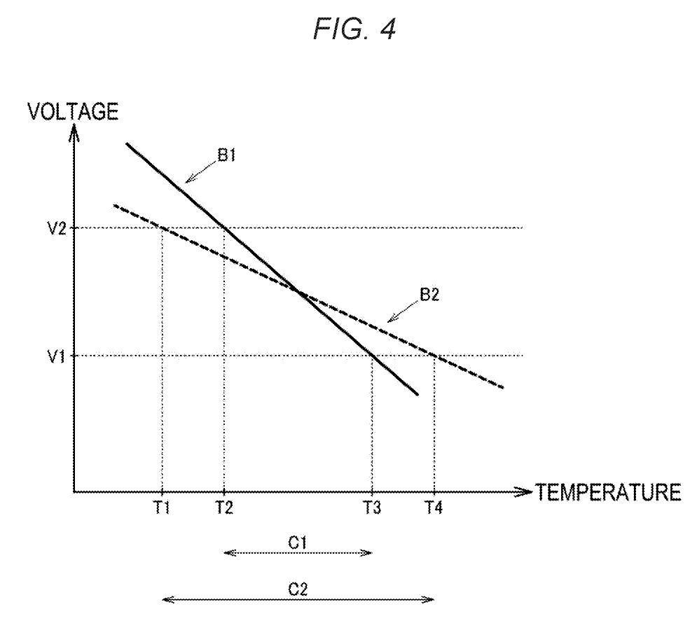

FIG. 4 shows a comparison between the temperature characteristic of the output voltage in the power supply circuit 10 to which the method of the present embodiment is applied and the temperature characteristic of the output voltage in the reference example in FIG. 3. The temperature characteristic of the output voltage in the reference example is as indicated by B1, and the temperature characteristic of the output voltage in the power supply circuit 10 to which the method of the present embodiment is applied is as indicated by B2. Assuming that a range from a voltage V1 to a voltage V2 is an allowable error range of the output voltage, the error range is a range from a temperature T2 to a temperature T3 as indicated by C1 in the reference example. In other words, the range indicated by C1 is a guaranteed operating temperature of an electronic apparatus including the regulator shown in the reference example. Meanwhile, in the case of the power supply circuit 10 to which the method of the present embodiment is applied, the temperature range in which the error of the output voltage is allowed is a range from a temperature T1 to a temperature T4 as indicated by C2. The temperature T1 is lower than the temperature T2, and the temperature T4 is higher than the temperature T3. This is because the gradient of the temperature characteristic determined by the temperature characteristic of the work function difference voltage is lower than the gradient of the temperature characteristic determined by the temperature characteristic of the threshold voltage of the diode-connected P-type transistor.

As described above, the method of eliminating the resistor can also be realized in the reference example, but the method according to the reference example cannot achieve the improvement of the temperature characteristics of the output voltage at the same time. In this regard, it can be said that the power supply circuit 10 to which the method of the present embodiment is applied is more advantageous because the temperature characteristics of the output voltage can be improved, and at the same time, the chip area can be reduced since no resistor is used.

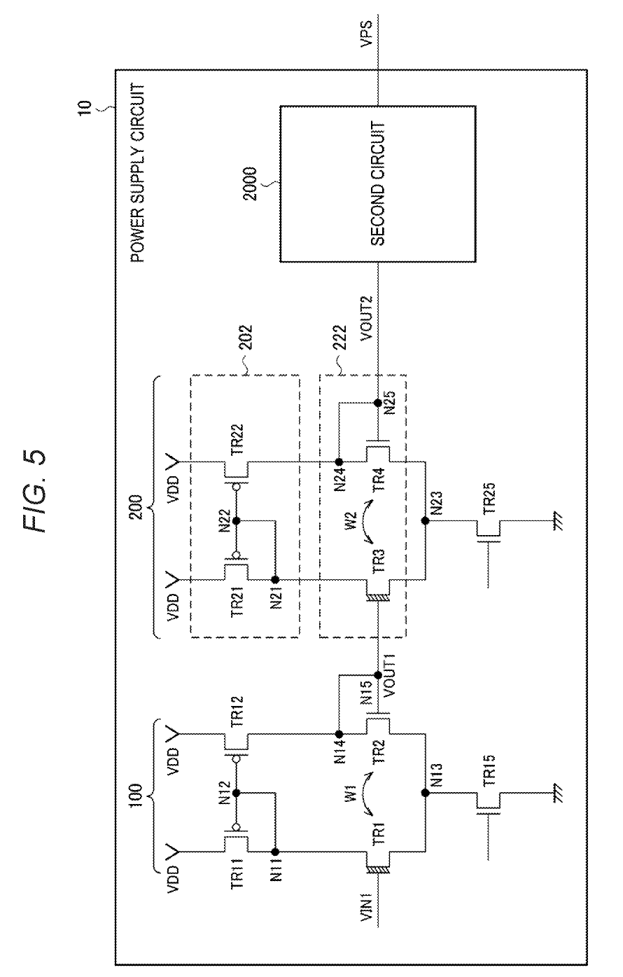

The power supply circuit 10 of the present embodiment will be described in more detail. As shown in FIG. 5, the power supply circuit 10 of the present embodiment further includes a second amplifier 200 in addition to the first amplifier 100 described above. A second output voltage VOUT2 is output from the second amplifier 200, and the power supply voltage VPS is output via a second circuit 2000. That is, there is a relationship in which the first circuit 1000 in FIG. 2 includes the second amplifier 200 and the second circuit 2000 in FIG. 5. For example, the second circuit 2000 buffers the second output voltage VOUT2 and outputs the power supply voltage VPS the same in voltage value as the second output voltage VOUT2. A detailed example of the second circuit 2000 will be described later. Note that the second circuit 2000 may be omitted, and the second output voltage VOUT2 may be output as the power supply voltage VPS. Note that in the description of FIG. 5, the description of the first amplifier 100 already described with reference to FIG. 2 will be omitted as appropriate.

The second amplifier 200 includes a second load section 202 and a second differential pair 222. The second load section 202 is a load of the second differential pair 222 and supplies a current to the second differential pair 222. For example, the second load section 202 includes a transistor TR21 as a P-type transistor and a transistor TR22 as a P-type transistor, and the transistor TR21 and the transistor TR22 constitute a current mirror circuit. More specifically, the transistor TR21 has the source coupled to the power supply voltage node, the drain coupled to a node N21, and the gate coupled to a node N22. Further, the transistor TR22 has the source coupled to the power supply voltage node, the drain coupled to a node N24, and the gate coupled to the node N22.

The second differential pair 222 is configured with a third transistor TR3 as an N-type transistor and a fourth transistor TR4 as an N-type transistor. The third transistor TR3 has the drain coupled to the node N21, and the source coupled to a node N23. The fourth transistor TR4 has the drain coupled to the node N24, the source coupled to the node N23, and the gate coupled to a node N25.

In addition, a transistor TR25 in FIG. 5 is an N-type transistor, and has the drain coupled to the node N23, the source coupled to the ground node, and the gate coupled to the bias voltage generation circuit. That is, similarly to the transistor TR15 described above with reference to FIG. 2, the transistor TR25 operates as a current source of the second amplifier 200 based on the bias voltage output from the bias voltage generation circuit.

The second amplifier 200 configured as described above outputs the second output voltage VOUT2. Specifically, the second output voltage VOUT2 is output from the node N24 in FIG. 5. In addition, the drain and the gate of the fourth transistor TR4 are coupled by being coupled to the node N24 and the node N25. That is, a node coupled to the gate of the third transistor TR3 corresponds to a node at the inverting terminal side of the second amplifier 200, the node N25 corresponds to the node at the non-inverting terminal side of the second amplifier 200, and the node N24 corresponds to an output node of the second amplifier 200.

Further, in the second amplifier 200, the third transistor TR3 is an N-type transistor of the depletion type similarly to the first transistor TR1, and the fourth transistor TR4 is an N-type transistor of the enhancement type similarly to the second transistor TR2. That is, the work function of the gate electrode of the third transistor TR3 and the work function of the gate electrode of the fourth transistor TR4 are different from each other, and that difference is referred to as a "second work function difference voltage W2" in the present embodiment. Therefore, the second output voltage VOUT2 output from the node N24 becomes the sum of the first output voltage VOUT1 and the second work function difference voltage W2 unless a second offset voltage described later is taken into consideration. As described above, since the second output voltage VOUT2 is based on the first work function difference voltage W1 and the second work function difference voltage W2, the temperature characteristics of the output voltage are improved compared to the reference example described above.

As described above, the power supply circuit 10 of the present embodiment includes the second amplifier 200 including the second differential pair 222 configured with the third transistor TR3 and the fourth transistor TR4, and the second load section 202 as the load of the second differential pair 222. Further, in the power supply circuit 10, the first output voltage VOUT1 is input to the gate of the third transistor TR3, and the drain and the gate of the fourth transistor TR4 are coupled to each other. Further, the second amplifier 200 outputs the second output voltage VOUT2 from the drain of the fourth transistor TR4 based on the second work function difference voltage W2 between the third transistor TR3 and the fourth transistor TR4. In this way, the temperature characteristics of the output voltage can be improved, and at the same time, the second output voltage VOUT2 larger in magnitude than the first output voltage VOUT1 can be output from the power supply circuit 10.

Further, the size of the fourth transistor TR4 may be different from the size of the third transistor TR3. Specifically, for example, the gate width of the fourth transistor TR4 may be made a predetermined multiple of the gate width of the third transistor TR3, or the gate length of the fourth transistor TR4 may be made shorter than the gate length of the third transistor TR3 by a certain ratio. Accordingly, an offset voltage is generated similarly to the first offset voltage described above. In the present embodiment, this voltage as the difference is referred to as a second offset voltage.

For example, when it is desired to output 1.8 V from the power supply circuit 10, the second output voltage VOUT2 can be set to 1.8 V by setting the first amplifier 100 so that the first output voltage VOUT1 is 0.9 V and setting the second amplifier 200 to have the same configuration as that of the first amplifier 100. In this case, it is sufficient to make the third transistor TR3 the same as the first transistor TR1, and to make the fourth transistor TR4 the same as the second transistor TR2. In addition, it is sufficient to make the second load section 202 and the first load section 101 substantially the same in configuration as each other, and to make the transistor TR15 and the transistor TR25 as the current sources the same as each other. However, the magnitude of the first output voltage VOUT1 may be made different from the magnitude of the second output voltage VOUT2. In other words, the configurations of the first amplifier 100 and the second amplifier 200 of the present embodiment are not required to be the same as each other. Further, the second offset voltage may be positive. In this case, the gate width of the fourth transistor TR4 may be smaller than the gate width of the third transistor TR3, or the gate length of the fourth transistor TR4 may be shorter than the gate length of the third transistor TR3.

As described above, in the power supply circuit 10 of the present embodiment, the second amplifier 200 outputs, as the second output voltage VOUT2, an added voltage obtained by adding the first output voltage VOUT1 and a voltage obtained by offsetting the second work function difference voltage W2 with the second offset voltage based on the size ratio between the third transistor TR3 and the fourth transistor TR4. In this way, it is possible to construct the power supply circuit 10 capable of adjusting the magnitude of the second output voltage VOUT2 while improving the temperature characteristics of the second output voltage VOUT2.

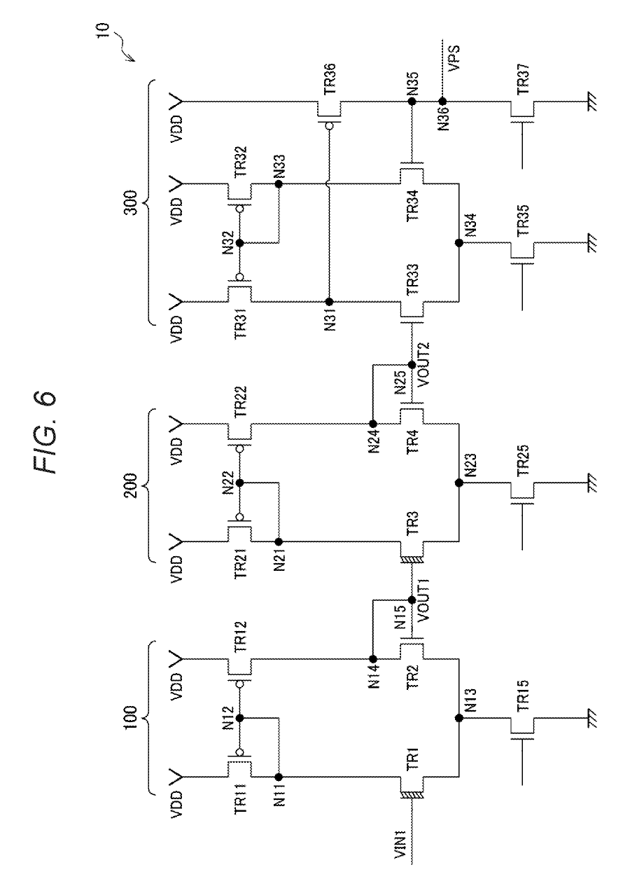

FIG. 6 is a diagram illustrating the power supply circuit 10 in FIG. 5 in more detail. The power supply circuit 10 of the present embodiment further includes an impedance conversion circuit 300 in addition to the first amplifier 100 and the second amplifier 200 described above. That is, the impedance conversion circuit 300 of FIG. 6 corresponds to the second circuit 2000 in FIG. 5.

The impedance conversion circuit 300 is a circuit having an output impedance lower than the output impedance of the second amplifier 200. That is, the impedance conversion circuit 300 is a circuit for converting the output impedance of the second amplifier 200 into a lower output impedance to output the power supply voltage VPS. The impedance conversion circuit 300 includes transistors TR31, TR32, TR33, TR34, TR35, TR36, and TR37. A current mirror circuit is configured with the transistor TR31 as a P-type transistor and the transistor TR32 as a P-type transistor, and supplies a current to the transistors TR33, TR34. The transistor TR31 has the source coupled to the power supply node, the drain coupled to a node N31, and the gate coupled to a node N32. The transistor TR32 has the source coupled to the power supply node, the drain coupled to a node N33, and the gate coupled to the node N32.

The transistor TR33 as an N-type transistor and the transistor TR34 as an N-type transistor constitute a differential pair. The transistor TR33 has the drain coupled to the node N31, the source coupled to a node N34, and the gate coupled to the node N25. That is, the second output voltage VOUT2 described above is input to the gate of the transistor TR33. The transistor TR34 has the drain coupled to the node N33, the source coupled to the node N34, and the gate coupled to a node N35. The transistor TR35 has the drain coupled to the node N34, the source coupled to the ground node, and the gate coupled to the bias voltage generation circuit. That is, similarly to the transistor TR15 and the transistor TR25 described above, the transistor TR35 operates as a current source of the impedance conversion circuit 300 based on the bias voltage output from the bias voltage generation circuit.

The transistor TR36 as a P-type transistor and the transistor TR37 as an N-type transistor constitute an output stage of the impedance conversion circuit 300. The transistor TR36 has the source coupled to the power supply node, the drain coupled to the node N35, and the gate coupled to the node N31. The transistor TR37 has the source coupled to the ground node, the drain coupled to a node N36 which is an output node of the impedance conversion circuit 300, and the gate coupled to the bias voltage generation circuit. That is, the transistor TR37 operates as a current source of the impedance conversion circuit 300 similarly to the transistor TR35. Note that the node N36 is the same in potential as the node N35.

The impedance conversion circuit 300 does not include a feedback resistor or an element that can be regarded as the same, and buffers the second output voltage VOUT2 output from the second amplifier 200 and outputs the second output voltage VOUT2 as the power supply voltage VPS. That is, the impedance conversion circuit 300 is a voltage follower circuit.

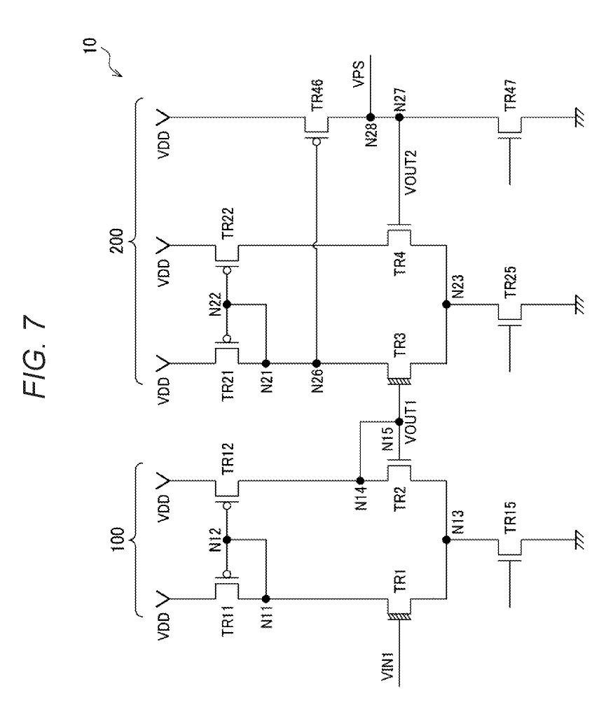

FIG. 7 shows, as another configuration example, the power supply circuit 10 when the power supply circuit 10 does not include the impedance conversion circuit 300. That is, FIG. 7 shows a configuration example in which the second amplifier 200 is provided with an output impedance equivalent to that of the impedance conversion circuit 300. The second amplifier 200 in FIG. 7 is different from that in FIG. 4 in that the second amplifier includes a transistor TR46 and a transistor TR47. The transistor TR46 as a P-type transistor has the source coupled to the power supply node, the drain coupled to a node N28 as an output node, and the gate coupled to a node N26. The node N26 is coupled to the drain of the third transistor TR3 described above. The transistor TR47 as an N-type transistor has the source coupled to the ground node, the drain coupled to a node N27, and the gate coupled to the bias voltage generation circuit. That is, similarly to the transistor TR25 described above, the transistor TR47 operates as a current source of the second amplifier 200 based on the bias voltage output from the bias voltage generation circuit. The node N27 is coupled to the gate of the fourth transistor TR4.

Note that although the power supply circuit 10 can be configured as shown in FIG. 7, when the voltage VDD is low, the configuration of FIG. 6 is superior in the following points. In the first amplifier 100 of the present embodiment, since the work function difference between the gate electrodes of the transistors constituting the differential pair is used, it is necessary to consider the balance of the voltage of a differential stage. For example, when the voltage VDD is set to 3 V, the input voltage VIN1 is set to 0 V, and the first output voltage VOUT1 is set to 0.9 V, the voltage at the drain side of the first transistor TR1 is about 2.3 V. In the comparative example in FIG. 7, when the second amplifier 200 is provided with substantially the same configuration as that of the first amplifier 100 and is coupled to the first amplifier 100, the voltage of the node N26 coupled to the drain of the third transistor TR3 becomes about 2.7 V. That is, since a difference between a voltage at the source side and a voltage at the gate side of the transistor TR46 is as small as 3.0 V-2.7 V=0.3 V, in order to generate a desired current, it is necessary to increase the size of the transistor TR46.

In this regard, by including the impedance conversion circuit 300 as illustrated in FIG. 7, the source-gate voltage of the transistor TR36 related to the output stage can further be increased, and therefore, a desired current can be generated without excessively increasing the size of the transistor TR36. Specifically, by increasing the current flowing through the current mirror circuit configured with the transistor TR31 and the transistor TR32, it is possible to decrease the voltage of the node N31, and increase the source-gate voltage of the transistor TR36.

As described above, the power supply circuit 10 of the present embodiment includes the impedance conversion circuit 300 that converts the output impedance of the second amplifier 200 to output the power supply voltage VPS. In this way, it is possible to construct the power supply circuit 10 that outputs a desired amount of current based on the power supply voltage VPS without increasing the size of the transistor related to the output stage.

As described above, in the power supply circuit 10 of the present embodiment, the impedance conversion circuit 300 is a voltage follower circuit. In this way, a desired amount of current can be output based on the power supply voltage VPS the same in magnitude as the second output voltage VOUT2.

As described above, the power supply circuit according to the present embodiment includes the first amplifier including the first differential pair configured with the first transistor and the second transistor, and the first load section as the load of the first differential pair. Further, in the power supply circuit, an input voltage is input to the gate of the first transistor, and the drain and the gate of the second transistor are coupled to each other. In addition, the first amplifier outputs, as the first output voltage from the drain of the second transistor, the voltage obtained by offsetting the first work function difference voltage between the first transistor and the second transistor by the first offset voltage based on the size ratio between the first transistor and the second transistor.

In this way, since the first output voltage is output from the first amplifier using the first work function difference voltage, it becomes unnecessary to use the feedback resistor. Thus, the chip area related to the power supply circuit can be reduced. Accordingly, a manufacturing cost can be reduced. Further, since the magnitude of the first work function difference voltage depends on the material of the gate electrode, the temperature characteristics of the first output voltage can be improved. Accordingly, it is possible to construct the power supply circuit that achieves both the reduction of the chip area and the improvement of the temperature characteristics of the output voltage. In addition, since the first output voltage in which the first offset voltage based on the fact that the first transistor and the second transistor are different in the size ratio is further considered is output, it is possible to output the first output voltage different in magnitude from the first work function difference voltage.

Further, the power supply circuit may include the second amplifier including the second differential pair configured with the third transistor and the fourth transistor, and the second load section as the load of the second differential pair. In addition, in the power supply circuit, the first output voltage may be input to the gate of the third transistor, and the drain and the gate of the fourth transistor may be coupled to each other. Further, the second amplifier may output the second output voltage from the drain of the fourth transistor based on the second work function difference voltage between the third transistor and the fourth transistor.

In this way, the temperature characteristics of the output voltage can be improved, and at the same time, the second output voltage larger in magnitude than the first output voltage can be output from the power supply circuit.

Further, the second amplifier may output, as the second output voltage, the added voltage obtained by adding the first output voltage and the voltage obtained by offsetting the second work function difference voltage by the second offset voltage based on the size ratio between the third transistor and the fourth transistor.

In this way, it is possible to construct the power supply circuit capable of adjusting the magnitude of the second output voltage while improving the temperature characteristics of the second output voltage.

Further, the impedance conversion circuit that converts the output impedance of the second amplifier to output the power supply voltage may be provided.

In this way, it is possible to construct the power supply circuit that outputs the desired amount of current based on the power supply voltage without increasing the size of the transistor related to the output stage.

Further, the impedance conversion circuit may be a voltage follower circuit.

In this way, the desired amount of current can be output based on the power supply voltage the same in magnitude as the second output voltage.

Further, the first transistor may be a depletion-type MOS transistor, and the second transistor may be an enhancement-type MOS transistor.

In this way, since the gate electrode material of the first transistor and the gate electrode material of the second transistor are different from each other, the first amplifier can be made to operate as a work function difference amplifier.

Further, the size ratio between the first transistor and the second transistor may be the ratio between the gate widths or the ratio between the gate lengths.

In this way, the threshold voltage of the first transistor and the threshold voltage of the second transistor can be made different from each other to generate the first offset voltage.

Further, the first output voltage may be lower than the first work function difference voltage by the first offset voltage.

In this way, the first amplifier that outputs the first output voltage lower than the first work function difference voltage can be constructed.

Further, the gate width of the second transistor may be larger than the gate width of the first transistor, or the gate length of the second transistor may be shorter than the gate length of the first transistor.

In this way, since the current flowing through the second transistor can be increased to lower the threshold voltage, it is possible to generate the first offset voltage that applies an offset smaller than the first work function difference voltage.

Further, the present embodiment relates to the circuit device including the power supply circuit described above, the discharge circuit that supplies the power to the outside based on the battery voltage from the battery, and the discharge control circuit that controls the discharge circuit, wherein the power supply circuit operates based on the battery voltage and outputs the power supply voltage based on the first output voltage, and the discharge control circuit operates based on the power supply voltage.

Note that while the present embodiment has been described in detail above, a person skilled in the art could readily understand that many modifications can be made without substantively departing from the novel matters and advantages of the present disclosure. Therefore, all such modifications should fall within the scope of the present disclosure. For example, a term described at least once together with a different term having a broader meaning or the same meaning in the specification or the drawings can be replaced with that different term in any part of the specification or the drawings. Further, all the combinations of the present embodiment and the modifications also fall within the scope of the present disclosure. Further, the configurations, operations, and so on of the power supply circuit and the circuit device are not limited to those described in the embodiment, and various modified implementations can be made.

What is claimed is:

1. A power supply circuit comprising:
a first amplifier including a first differential pair configured with a first transistor and a second transistor, and a first load section as a load of the first differential pair, wherein
an input voltage is input to a gate of the first transistor, a drain and a gate of the second transistor are coupled to each other, and
the first amplifier outputs, as a first output voltage from the drain of the second transistor, a voltage obtained by offsetting a first work function difference voltage between the first transistor and the second transistor by a first offset voltage based on a size ratio between the first transistor and the second transistor.

2. The power supply circuit according to claim 1, further comprising
a second amplifier including a second differential pair configured with a third transistor and a fourth transistor, and a second load section as a load of the second differential pair, wherein
the first output voltage is input to a gate of the third transistor, a drain and a gate of the fourth transistor are coupled to each other, and
the second amplifier outputs a second output voltage from the drain of the fourth transistor based on a second work function difference voltage between the third transistor and the fourth transistor.

3. The power supply circuit according to claim 2, wherein
the second amplifier outputs, as the second output voltage, an added voltage obtained by adding the first output voltage and a voltage obtained by offsetting the second work function difference voltage by a second offset voltage based on a size ratio between the third transistor and the fourth transistor.

4. The power supply circuit according to claim 2, further comprising
an impedance conversion circuit configured to convert an output impedance of the second amplifier to output a power supply voltage.

5. The power supply circuit according to claim 4, wherein
the impedance conversion circuit is a voltage follower circuit.

6. The power supply circuit according to claim 1, wherein
the first transistor is a depletion-type MOS transistor, and
the second transistor is an enhancement-type MOS transistor.

7. The power supply circuit according to claim 1, wherein
the size ratio between the first transistor and the second transistor is a ratio of gate width or a ratio of gate length.

8. The power supply circuit according to claim 1, wherein
the first output voltage is lower than the first work function difference voltage by the first offset voltage.

9. The power supply circuit according to claim 8, wherein
a gate width of the second transistor is larger than a gate width of the first transistor, or
a gate length of the second transistor is shorter than a gate length of the first transistor.

10. A circuit device comprising:
the power supply circuit according to claim 1;
a discharge circuit configured to supply power to an outside based on a battery voltage from a battery; and
a discharge control circuit configured to control the discharge circuit, wherein
the power supply circuit operates based on the battery voltage to output a power supply voltage based on the first output voltage, and
the discharge control circuit operates based on the power supply voltage.
